(19) United States
(12) Patent Application Publication
(10) Pub. No.: US 2014/0001038 A1
(43) Pub. Date: Jan. 2, 2014

(54) Ferromagnetic Sputtering Target with Less Particle Generation

(71) Applicants: Shin-ichi Ogino, Ibaraki (JP); Atsushi Sato, Ibaraki (JP); Atsutoshi Arakawa, Ibaraki (JP); Yuichiro Nakamura, Ibaraki (JP)

(72) Inventors: Shin-ichi Ogino, Ibaraki (JP); Atsushi Sato, Ibaraki (JP); Atsutoshi Arakawa, Ibaraki (JP); Yuichiro Nakamura, Ibaraki (JP)

(73) Assignee: JX NIPPON MINING & METALS CORPORATION, Tokyo (JP)

(21) Appl. No.: 14/004,227

(22) PCT Filed: Apr. 6, 2012
(86) PCT No.: PCT/JP2012/059513

§ 371 Date: Sep. 10, 2013

(30) Foreign Application Priority Data
Aug. 23, 2011 (JP) 2011-181969

(51) Int. Cl. C23C 14/34

(52) U.S. Cl. CPC C23C 14/3414
USPC 204/298.13

(57) ABSTRACT

Provided is a nonmagnetic-material-dispersed sputtering target having a metal composition comprising 20 mol % or less of Cr and the balance of Co. The target has a structure including a phase (A) in which a nonmagnetic oxide material is dispersed in the basis metal, and a metal phase (B) containing 40 mol % or more of Co; the area proportion of grains of the nonmagnetic oxide material in the phase (A) is 50% or less; and when a minimum-area rectangle circumscribed to the phase (B) is assumed, the proportion of the circumscribed rectangle having a short side of 2 to 300 μm is 90% or more of all of the phases (B). The ferromagnetic sputtering target can suppress particle generation during sputtering and can improve leakage magnetic flux to allow stable electrical discharge with a magnetron sputtering apparatus.

### TECHNICAL FIELD

The present invention relates to a ferromagnetic sputtering target that is used for forming a magnetic thin film of a magnetic recording medium, in particular, for forming a magnetic recording layer of a hard disk employing a perpendicular magnetic recording system. The sputtering target has less particle generation and a large leakage magnetic flux and can thereby achieve stable electrical discharge during sputtering with a magnetron sputtering apparatus.

### BACKGROUND ART

In the field of magnetic recording represented by hard disk drives, ferromagnetic metal-based materials, such as Co, Fe, or Ni-based materials, are used for magnetic thin films that carry out recording. For example, in recording layers of hard disks employing a longitudinal magnetic recording system, Co—Cr based or Co—Cr—Pt based ferromagnetic alloys mainly containing Co have been used.

Further, in recording layers of hard disks employing a perpendicular magnetic recording system, which has been applied to practical use recently, composite materials composed of Co—Cr—Pt based ferromagnetic alloys mainly containing Co and nonmagnetic inorganic materials are widely used.

Many of magnetic thin films of magnetic recording media such as hard disks are produced by sputtering a ferromagnetic sputtering target composed of the above-mentioned materials, because of the high productivity.

As methods of producing these ferromagnetic sputtering targets, a melting method and a powder metallurgy method are proposed. Though which method is used for producing a target depends on the required characteristics, the sputtering target composed of a ferromagnetic alloy and nonmagnetic inorganic grains to be used for forming a recording layer of a hard disk in a perpendicular magnetic recording system is usually produced by the powder metallurgy method. This is because though the inorganic grains in such a target are required to be uniformly dispersed in the alloy base material, and it is difficult to produce the target by the melting method.

For example, a method of producing a sputtering target for a magnetic recording medium by: mixing a powder mixture prepared by mixing a Co powder, a Cr powder, a TiO₂ powder and a SiO₂ powder, with a Co spherical powder using a planetary-screw mixer; and molding the resulting powder mixture by hot pressing, has been proposed (Patent Document 1).

In the structure of such a target, spherical metal phases (B) having a higher magnetic permeability than that of the surrounding composition are observed in a phase (A), as a basis metal, in which inorganic grains are dispersed (FIG. 1 in Patent Document 1). Such a structure is advantageous for improving the leakage magnetic flux, but it is not a suitable sputtering target for a magnetic recording medium from the viewpoint of suppressing particle generation during sputtering.

Furthermore, a method of producing a sputtering target for a magnetic recording medium by: pulverizing and mixing a powder mixture prepared by mixing a Co powder, a Cr powder and a SiO₂ powder, with a Co atomized powder in an attritor; and molding the resulting powder mixture by hot pressing, has been proposed (Patent Document 2).

In the structure of such a target, wedge-shaped metal phases (B) having a higher magnetic permeability than that of the surrounding composition are observed in a phase (A) as a basis metal (FIG. 1 in Patent Document 2). Such a structure is advantageous for suppressing particle generation during sputtering, but it is not a suitable sputtering target for a magnetic recording medium from the viewpoint of improving the leakage magnetic flux.

Furthermore, a method of producing a sputtering target for a Co-based alloy magnetic film by: mixing a SiO₂ powder with a Co—Cr—Ta alloy powder produced by an atomizing method; mechanically alloying the resulting mixture with a ball mill to disperse an oxide in the Co—Cr—Ta alloy powder; and molding the powder mixture by hot pressing, has been proposed (Patent Document 3).

In the structure of such a target, though the diagram is unclear, a black portion (SiO₂) surrounds a large white spherical composition (Co—Cr—Ta alloy). Such a structure is also not a suitable sputtering target for a magnetic recording medium.

Furthermore, a method of producing a sputtering target for forming a magnetic recording medium thin film by mixing a Co—Cr binary system alloy powder, a Pt powder and a SiO₂ powder, and subjecting the resulting powder mixture to hot pressing, has been proposed (Patent Document 4).

In the structure of such a target, though it is not shown by any diagram, it is described that there are a Pt phase, a SiO₂ phase and a Co—Cr binary system alloy phase, and a diffusion layer surrounding the Co—Cr binary system alloy layer is observed. Such a structure is also not a suitable sputtering target for a magnetic recording medium.

Though various systems are known as sputtering apparatuses, in formation of magnetic recording films, magnetron sputtering apparatuses equipped with DC power sources are widely used because of the high productivity. Sputtering is a method of generating an electric field by applying a high voltage between a substrate serving as a positive electrode and a target serving as a negative electrode disposed so as to face each other under an inert gas atmosphere.

On this occasion, the inert gas is ionized into plasma composed of electrons and cations. The cations in the plasma collide with the surface of the target (negative electrode) to make the target constituent atoms fly out from the target, and the flying out atoms adhere to the facing substrate surface to form a film. Sputtering is based on the principle that a film of the material constituting a target is formed on a substrate by such series of actions.
Patent Document 1: Japanese Patent Application No. 2010-011326
Patent Document 2: Japanese Patent Application No. 2011-502582
Patent Document 3: Japanese Patent Laid-Open No. H10-088333
Patent Document 4: Japanese Patent Laid-Open No. 2009-1860

### SUMMARY OF INVENTION

### Technical Problem

In general, in sputtering of a ferromagnetic sputtering target with a magnetron sputtering apparatus, most of the magnetic flux from a magnet passes through the target made of a ferromagnetic material to reduce the leakage magnetic flux, resulting in a big problem of no discharge or unstable discharge in sputtering.

In order to solve this problem, it is known to improve the leakage magnetic flux by incorporating coarse metal grains of about 30 to 150 μm during the process of producing a sputtering target. The leakage magnetic flux tends to increase with the incorporated amount of the coarse metal grains, but the content of oxide dispersed in the basis metal also increases, and thereby increases the agglomeration of oxides. As a result, the oxides agglomerated in the target are desorbed during sputtering and thereby cause a problem of particle generation.

Thus, conventionally, though stable discharge can be achieved, even in magnetron sputtering, by reducing the relative magnetic permeability of a sputtering target and thereby increasing the leakage magnetic flux, particles tend to increase because that oxide agglomerates are detached (desorbed) during sputtering.

It is an object of the present invention in view of the above-mentioned problems to provide a ferromagnetic sputtering target, by using which stable electrical discharge can be achieved in a magnetron sputtering apparatus, particle generation is reduced during sputtering, and leakage magnetic flux is improved.

### Solution to Problem

In order to solve the above-described problems, the present inventors have diligently studied and, as a result, have found that a target having a large leakage magnetic flux and less generation of particles can be obtained by adjusting the composition structure of the target.

Based on these findings, the present invention provides:

1) a nonmagnetic-material-dispersed sputtering target having a metal composition comprising 20 mol % or less of Cr and the balance of Co, wherein the target structure includes a phase (A) in which a nonmagnetic oxide material is dispersed in a basis metal, and a metal phase (B) containing 40 mol % or more of Co; the area proportion of grains of the nonmagnetic oxide material in the phase (A) is 50% or less; and when a minimum-area rectangle circumscribed to the phase (B) is assumed, the proportion of the circumscribed rectangle having a short side of 2 to 300 μm is 90% or more of all of the phases (B).

The present invention also provides:

2) a nonmagnetic-material-dispersed sputtering target having a metal composition comprising 20 mol % or less of Cr, 5 mol % or more and 30 mol % or less of Pt, and the balance of Co, wherein the target structure includes a phase (A) in which a nonmagnetic oxide material is dispersed in a basis metal, and a metal phase (B) containing 40 mol % or more of Co; the area proportion of grains of the nonmagnetic oxide material in the phase (A) is 50% or less; and when a minimum-area rectangle circumscribed to the metal phase (B) is assumed, the proportion of the circumscribed rectangle having a short side of 2 to 300 μm is 90% or more of all of the phases (B).

The present invention also provides:

3) a nonmagnetic-material-dispersed sputtering target having a metal composition comprising 5 mol % or more and 30 mol % or less of Pt and the balance of Co, wherein the target structure includes a phase (A) in which a nonmagnetic oxide material is dispersed in a basis metal, and a metal phase (B) containing 40 mol % or more of Co; the area proportion of grains of the nonmagnetic oxide material in the phase (A) is 50% or less; and when a minimum-area rectangle circumscribed to the metal phase (B) is assumed, the proportion of the circumscribed rectangle having a short side of 2 to 300 μm is 90% or more of all of the phases (B).

The present invention further provides:

4) the nonmagnetic-material-dispersed ferromagnetic sputtering target according to any one of 1) to 3), wherein when a minimum-area rectangle circumscribed to the metal phase (B) is assumed, the aspect ratio of the circumscribed rectangle is 1:1 to 1:15; and
5) the ferromagnetic sputtering target according to any one of 1) to 4), wherein the basis metal further contains at least one additional element selected from B, Ti, V, Mn, Zr, Nb, Ru, Mo, Ta and W in an amount of 0.5 mol % or more and 10 mol % or less, and the balance is Co.

### Advantageous Effects of Invention

The thus-prepared target has a large leakage magnetic flux to efficiently accelerate ionization of an inert gas to give stable discharge when used in a magnetron sputtering apparatus. It is possible to increase the thickness of the target to enable a reduction in frequency of replacement of the target with a new one, resulting in an advantage of reducing the manufacturing cost of magnetic thin films. In addition, since the particle generation is low, production of defective magnetic recording films by sputtering decreases, which also results in an advantage of reducing the cost.

### BRIEF DESCRIPTION OF DRAWINGS

FIG. 1 This is a structural image of a target in Example 1 observed with an optical microscope.

FIG. 2 This is a structural image of a target in Comparative Example 1 observed with an optical microscope.

FIG. 3 This is a structural image of a target in Example 2 observed with an optical microscope.

FIG. 4 This is a structural image of a target in Comparative Example 2 observed with an optical microscope.

FIG. 5 This is a structural image of the phase (A) in Example 2 observed with an optical microscope.

### DESCRIPTION OF EMBODIMENTS

As the metal components constituting the ferromagnetic sputtering target of the present invention, proposed are a metal comprising 20 mol % or less of Cr and the balance of Co, or a metal comprising 20 mol % or less of Cr, 5 mol % or more and 30 mol % or less of Pt, and the balance of Co. The content of Cr is higher than 0 mol %; that is, the Cr content is higher than the analyzable lower limit. Furthermore, as long as the Cr content is 20 mol % or less, the effects can be obtained even if the amount of Cr is small. The present invention encompasses such cases.

Alternatively, as the metal components constituting the ferromagnetic sputtering target of the present invention, proposed is a metal comprising 5 mol % or more and 30 mol % or less of Pt and the balance of Co. The blending ratios can be varied within the above-mentioned ranges, while the characteristics as an effective magnetic recording medium being maintained.

In the present invention, the composition of the target forms a structure in which metal phases (B) having a higher magnetic permeability than that of the surrounding composition are isolated from each other by the phase (A) composed of a basis metal and nonmagnetic oxide grains dispersed in the basis metal.

In the present invention, it is important to control the area proportion of grains of the nonmagnetic oxide material to the area of the phase (A) in an arbitrary cross section of the sputtering target (hereinafter, similarly, the area proportion, the phase shape, and the size mean those in an arbitrary cross section, throughout the specification).

The area proportion of grains of the nonmagnetic oxide material is desirably 50% or less. An area proportion higher than 50% forms a structure in which a metal component in island forms are dispersed in the oxide to readily cause agglomeration of the oxide. Accordingly, the area proportion is desirably 50% or less.

The area proportion of grains of the nonmagnetic oxide material can be adjusted by changing the relative amounts of the Co powder and Co atomized powder (or Co coarse powder). That is, when the relative amount of the Co powder is increased and when the relative amount of the Co atomized powder (or Co coarse powder) is decreased, the amount of Co in the phase (A) relatively increases to reduce the area proportion of grains of the nonmagnetic oxide material.

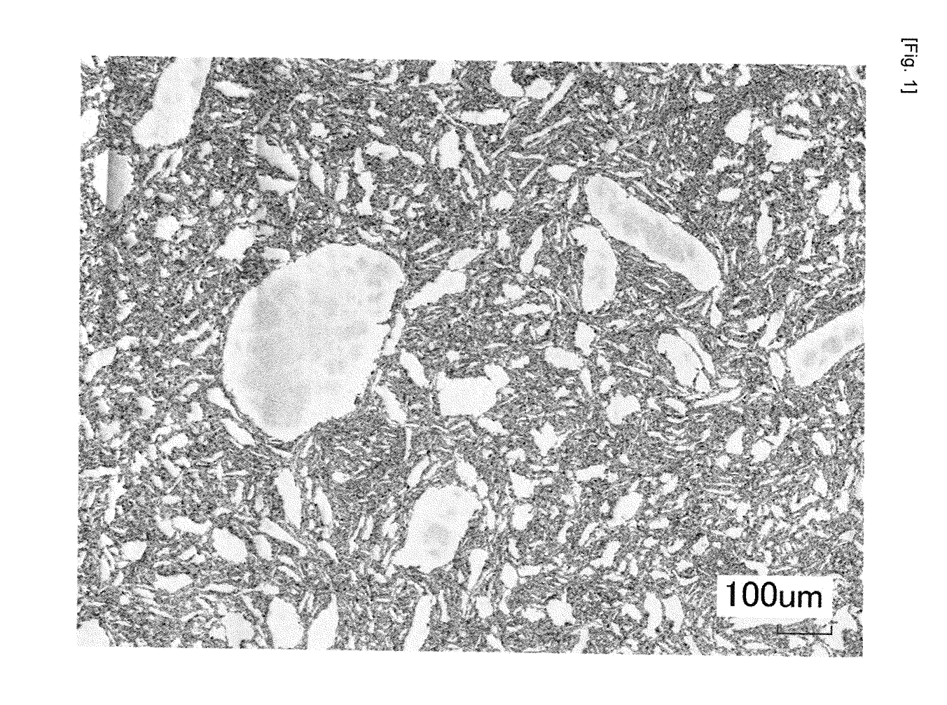

In the metal phase (B), when a minimum-area rectangle circumscribed to the metal phase (B) is assumed, the short side of the rectangle is desirably 2 to 300 μm. As shown in FIG. 1, the phase (A) includes fine inorganic oxide grains (in FIG. 1, the finely dispersed black portion is the inorganic grains). When a minimum-area rectangle circumscribed to the metal phase (B) is assumed, if the short side of the circumscribed rectangle is smaller than 2 μm, the difference in size between the inorganic grains and the coexisting metal grains is small. In sintering of such a target material, diffusion of the metal phase (B) proceeds to make the presence of the metal phase (B) unclear, resulting in loss of the effect of increasing the leakage magnetic flux density.

Accordingly, in the phase (B), it is better that rectangles having a short side of less than 2 μm is as less as possible. The length of the short side required to be a certain length or more is a determinant of the action/effect of the metal phase (B) on the leakage magnetic flux density, and the short side is therefore required to be restricted. From this meaning, it would be understood that the restriction of the long side, which is longer than the short side, is unnecessary excluding the case of restricting a better range as described below.

In contrast, when the length of the short side is longer than 300 μm, the smoothness of the target surface decreases with the progress of sputtering. This may readily cause a problem of particles. Accordingly, when a minimum-area rectangle circumscribed to the metal phase (B) is assumed, the short side of the circumscribed rectangle is preferably 2 to 300 μm, and the proportion of such metal phases (B) is preferably 90% or more and more preferably 95% or more of all of the phases (B).

In particular, it is preferred not to contain a metal phase of which circumscribed rectangle has a short side of longer than 300 μm. Even if the phase (B) of which circumscribed rectangle has a short side of shorter than 2 μm is present in an amount of about 10%, it is substantially negligible. That is, the presence of the phase (B) of which rectangle has a short side of 2 to 300 μm is important and meaningful. From the above, the proportion of the phase (B) of which rectangle has a short side of 2 to 300 μm can be defined to be 90% or more and more preferably 95% or more of all of the phases (B).

In addition, in the present invention, when a minimum-area rectangle circumscribed to the metal phase (B) is assumed, the aspect ratio of the rectangle is desirably 1:1 to 1:15. The aspect ratio of the rectangle is the ratio of the short side length to the long side length. When the short side is 2 μm, the long side in an aspect ratio of 1:15 is in a range of 2 to 30 μm. If the short side is longer than the above, the long side also lengthens, but a larger aspect ratio of the rectangle may form a string-shaped atypical metal phase (B). Accordingly, it is desirable that the aspect ratio of the rectangle circumscribed the phase (B) is 1:1 to 1:15.

However, this is not an absolute requirement, and the string-shaped atypical metal phase (B) is also an acceptable condition in the present invention. Thus, in the present invention, detachment of the metal phase can be prevented, and thereby the amount of generated particles, which causes a reduction in yield, can be reduced.

In addition, in the present invention, the metal phase (B) is desirably a Co alloy phase containing 40 mol % or more of Co. In such a case, the target has a large leakage magnetic flux to provide stable discharge and thereby has characteristics suitable as a ferromagnetic sputtering target. In order to maintain a high maximum magnetic permeability of the metal phase (B), a higher concentration of Co is desirable. The Co content in the metal phase (B) can be measured with an EPMA, but the method is not limited thereto, and any analytical method that can measure the Co amount in the phase (B) can be similarly employed.

In addition, in the present invention, the basis metal can further contain at least one additional element selected from B, Ti, V, Mn, Zr, Nb, Ru, Mo, Ta and W in an amount of 0.5 mol % or more and 10 mol % or less. Accordingly, when these elements are contained, the balance is Co. These elements are contained as needed for improving the characteristics as a magnetic recording medium.

The thus-prepared target has a large leakage magnetic flux to efficiently accelerate ionization of an inert gas to give stable discharge when used in a magnetron sputtering apparatus. It is possible to increase the thickness of the target to enable a reduction in frequency of replacement of the target with a new one, resulting in an advantage of reducing the manufacturing cost of magnetic thin films.

Furthermore, variation in erosion rate can be reduced, and detachment of the metal phase can be prevented. As a result, an advantage of reducing the amount of generated particles, which causes a reduction in yield, can be provided.

The ferromagnetic sputtering target of the present invention can be produced by a powder metallurgy method. First, powders of the respective metal elements and, as needed, a powder of additional metal element are prepared. These powders desirably each have a maximum grain diameter of 20 μm or less. Instead of the powders of each metal element, an alloy powder of these metals may be prepared. In also such a case, the maximum grain diameter is desirably 20 μm or less.

However, a too small grain diameter accelerates oxidation to cause problems such that the component composition changes to the outside of the necessary range. Accordingly, the diameter is also desirably 0.1 μm or more.

Subsequently, the metal powders are weighed to give a desirable composition and are mixed and pulverized with a known procedure using, for example, a ball mill. When an inorganic material powder is added, the powder may be mixed with the metal powders on this occasion.

As the inorganic material powder, an oxide powder is prepared. The inorganic material powder desirably has a maximum grain diameter of 5 μm or less. Since a too small grain diameter tends to agglomerate, the diameter is also desirably 0.1 μm or more.

As a part of the Co raw material, a Co coarse powder or a Co atomized powder is used. On this occasion, the blending ratio of the Co coarse powder or the Co atomized powder is appropriately controlled such that the area proportion of the oxide does not exceed 50%. A Co atomized powder having a diameter in a range of 50 to 150 μm is prepared, and the Co atomized powder and the powder mixture described above are pulverized and mixed with an attritor.

Herein, as the mixer, for example, a ball mill or a mortar can be used, but it is desirable to use a strong mixing method such as a ball mill.

In addition, the prepared Co atomized powder is separately pulverized into a Co coarse powder having a diameter in a range of 50 to 300 μm, and the coarse powder may be mixed with the powder mixture. The mixer is preferably, a ball mill, a Pneugra-machine (agitator), a mixer, or a mortar. In light of the problem of oxidation during mixing, mixing is preferably performed in an inert gas atmosphere or in vacuum.

The thus-prepared powder is molded and sintered with a vacuum hot-pressing apparatus, followed by cutting into a desired shape to produce a ferromagnetic sputtering target of the present invention. The Co powder having a broken shape due to pulverization has become a flat or spherical metal phase (B), which is observed in the structure of the target, in many cases.

In addition, the molding and sintering is not limited to hot pressing and may be performed by plasma arc sintering or hot isostatic pressure sintering. The retention temperature for the sintering is preferably set to the lowest temperature in the temperature range in which the target is sufficiently densified. Though it depends on the composition of a target, in many cases, the temperature is in a range of 800 to 1200° C. Crystal growth of the sintered compact can be suppressed by performing the sintering at a lower temperature. The pressure in the sintering is preferably 300 to 500 kg/cm².

### EXAMPLES

The present invention will now be described by Examples and Comparative Examples. The Examples are merely exemplary and are not intended to limit the scope of the present invention. That is, the present invention is defined by the following claims only and encompasses various modifications in addition to the Examples contained in the specification.

### Example 1 and Comparative Example 1

In Example 1, a Co powder having an average grain diameter of 3 μm, a Cr powder having an average grain diameter of 5 μm, a Pt powder having an average grain diameter of 1 μm, a SiO₂ powder having an average grain diameter of 1 μm, and a Co coarse powder having a diameter in a range of 50 to 300 μm were prepared as raw material powders. These powders, the Co powder, the Cr powder, the Pt powder, the SiO₂ powder, and the Co coarse powder, were weighed to give a target composition of Co-12Cr-14Pt-8SiO₂ (mol %).

Subsequently, the Co powder, the Cr powder, the Pt powder, and the SiO₂ powder were charged into a 10-liter ball mill pot together with zirconia balls as the pulverizing medium, and the ball mill pot was sealed and rotated for 20 hours for mixing. The resulting powder mixture and the Co coarse powder were charged into an attritor and were pulverized and mixed.

The resulting powder mixture was loaded in a carbon mold and was hot-pressed in a vacuum atmosphere under conditions of a temperature of 1100° C., a retention time of 2 hours, and a pressure of 30 MPa to give a sintered compact. The sintered compact was cut with a lathe to give a disk-shaped target having a diameter of 180 mm and a thickness of 5 mm.

### (Evaluation of the Number of Particles)

In a film having a thickness that is usually employed in a product (the thickness of a recording layer is 5 to 10 nm), the difference in the number of particles is hardly observed. Accordingly, the number of particles was evaluated by increasing the absolute number of particles using a film having a thickness (1000 nm) about 200 times that of a usual film. The results are shown in Table 1.

### (Measurement of Leakage Magnetic Flux)

The leakage magnetic flux was measured in accordance with ASTM F2086-01 (Standard Test Method for Pass Through Flux of Circular Magnetic Sputtering Targets, Method 2). The target was fixed at the center thereof and was turned by 0, 30, 60, 90, and 120 degrees, and the leakage magnetic flux density of the target was measured at each angle and was divided by the reference field value defined in ASTM and multiplied by 100 to give a percentage value. The average of values at the five points is shown in Table 1 as the average leakage magnetic flux density (%).

### (Measurement of Size of Metal Phase (B) and Aspect Ratio)

The size of a metal phase (B) was measured using a cross section of a sintered compact (including a sputtering target) by assuming a rectangle (having a minimum area) circumscribed to each metal phase (B) existing in a viewing field of 220-magnification and measuring the short side and the long side of the rectangle.

The results demonstrate that when a minimum-area rectangle circumscribed to the metal phase (B) was assumed, most of the circumscribed rectangles had short side of 2 to 300 μm, that the proportion of rectangles having a short side shorter than 2 μm was less than 5%, and that no rectangles had a short side longer than 300 μm. The maximum aspect ratio and the minimum aspect ratio in one viewing field were determined for arbitrary five viewing fields, and the maximum value and the minimum value of the resulting aspect ratios were obtained. The metal phase (B) partially included in a viewing field was neglected. The results demonstrate that the aspect ratio of the circumscribed rectangle was in a range of 1:1 to 1:15. The results are shown in Table 1.

### (Measurement of Area Proportion of Oxide)

The proportion of the area occupied by an oxide can be determined by observing a cross section of a sintered compact (including a sputtering target) with a microscope. The area of the oxide existing in a viewing field of 220-magnification is measured and is divided by the total area of the viewing field. Specifically, since the metal phase looks white and the oxide looks black in a microscopic photograph, the respective areas can be calculated by binarizing the image using image processing software. In order to increase the accuracy, the measurement may be performed for arbitrary five viewing fields to calculate the average thereof. As in the measurement of aspect ratio, the oxide partially included in a viewing field was neglected. The results are shown in Table 1.

In Comparative Example 1, a Co powder having an average grain diameter of 3 μm, a Cr powder having an average grain diameter of 5 μm, a Pt powder having an average grain diameter of 1 μm, and a SiO₂ powder having an average grain diameter of 1 μm were prepared as raw material powders. These powders, the Co powder, the Cr powder, the Pt powder, and the SiO₂ powder, were weighed to give a target composition of Co-12Cr-14Pt-8SiO₂ (mol %). Neither Co coarse powder nor Co atomized powder was used.

These powders were charged into a 10-liter ball mill pot together with zirconia balls as the pulverizing medium, and the ball mill pot was sealed and rotated for 20 hours for mixing. Subsequently, the resulting powder mixture was loaded in a carbon mold and was hot-pressed in a vacuum atmosphere under conditions of a temperature of 1100° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 1 was 10.2 and was smaller than 10.4 in Comparative Example 1. It was also confirmed that the average leakage magnetic flux density in Example 1 was 61.3% and was notably improved compared to 47.1% in Comparative Example 1.

The results of observation with an optical microscope as described above demonstrate that the length of the short side of each rectangle circumscribed to the metal phase (B) was 2 to 300 μm, that the aspect ratio ranged from 1:1 to 1:15, and that spherical and flat phases existed in a mixed state. The area proportion of the oxide in the phase (A) was 38.00% and was confirmed to be 50% or less.

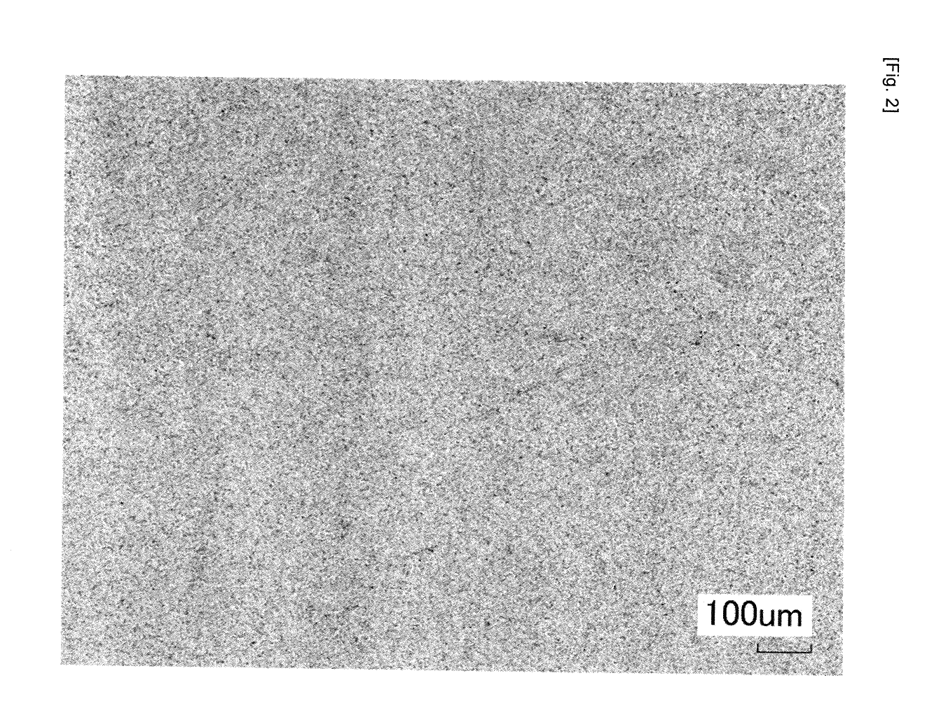

FIG. 1 shows a structural image of the polished surface of the target in Example 1 observed with an optical microscope, and FIG. 2 shows the image in Comparative Example 1. In FIG. 1, the blackish portion is the phase (A) in which the oxide is uniformly dispersed in a basis metal, and the white portion is the metal phase (B).

### Example 2 and Comparative Example 2-1

In Example 2, a Co powder having an average grain diameter of 3 μm, a Cr powder having an average grain diameter of 5 μm, a Pt powder having an average grain diameter of 1 μm, a SiO₂ powder having an average grain diameter of 1 μm, a Cr₂O₃ powder having an average grain diameter of 3 μm, and a Co atomized powder having a diameter in a range of 50 to 150 μm were prepared as raw material powders. These powders, the Co powder, the Cr powder, the Pt powder, the Ru powder, the SiO₂ powder, the Cr₂O₃ powder, and the Co atomized powder, were weighed to give a target composition of Co-9Cr-13Pt-4Ru-7SiO₂-3Cr₂O₃ (mol %).

Subsequently, the Co powder, the Cr powder, the Pt powder, the Ru powder, the SiO₂ powder, and the Cr₂O₃ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 2-1, a Co powder having an average grain diameter of 3 μm, a Cr powder having an average grain diameter of 5 μm, a Pt powder having an average grain diameter of 1 μm, a Ru powder having an average diameter of 8 μm, a SiO₂ powder having an average grain diameter of 1 μm, and a Cr₂O₃ powder having an average grain diameter of 3 μm were prepared as raw material powders. Neither Co coarse powder nor Co atomized powder was used. The powders, the Co powder, the Cr powder, the Pt powder, the Ru powder, the SiO₂ powder, and the Cr₂O₃ powder, were weighed to give a target composition of Co-9Cr-13Pt-4Ru-7SiO₂-3Cr₂O₃ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1100° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 2 was 11.1 and was slightly higher than 10.5 in Comparative Example 2-1, but a target still with less particles compared to those in conventional targets was obtained. The average leakage magnetic flux density in Example 2 was 65.7% to give a target having a higher leakage magnetic flux density than 40.1% in Comparative Example 2-1.

The results of observation with an optical microscope demonstrate that the length of the short side of each rectangle circumscribed to the metal phase (B) was 5 to 300 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 50.00% and was confirmed to be 50% or less.

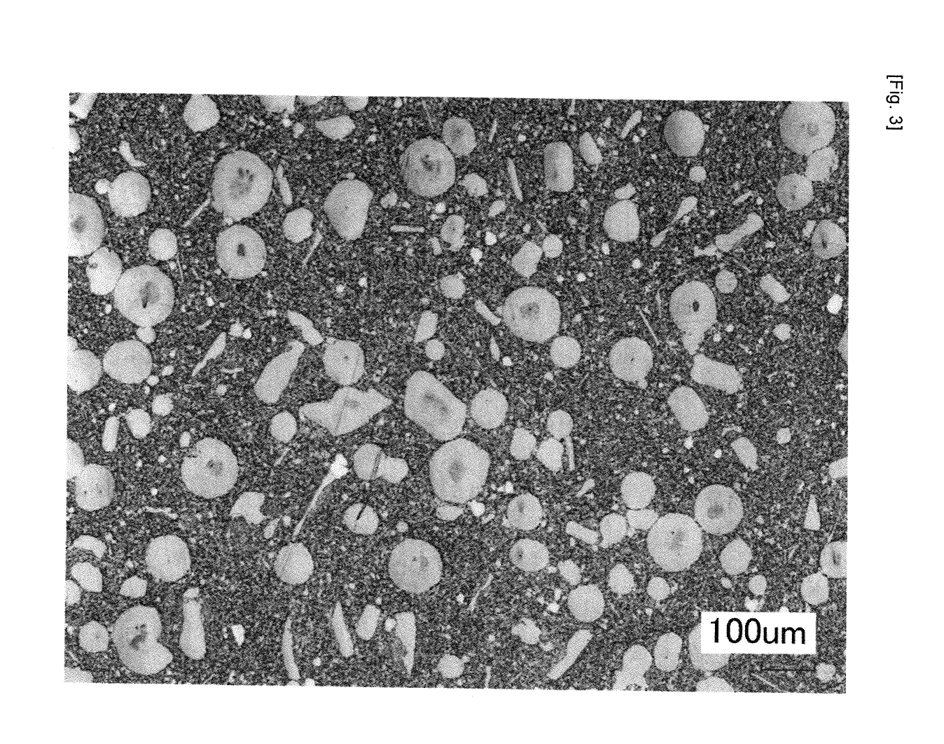

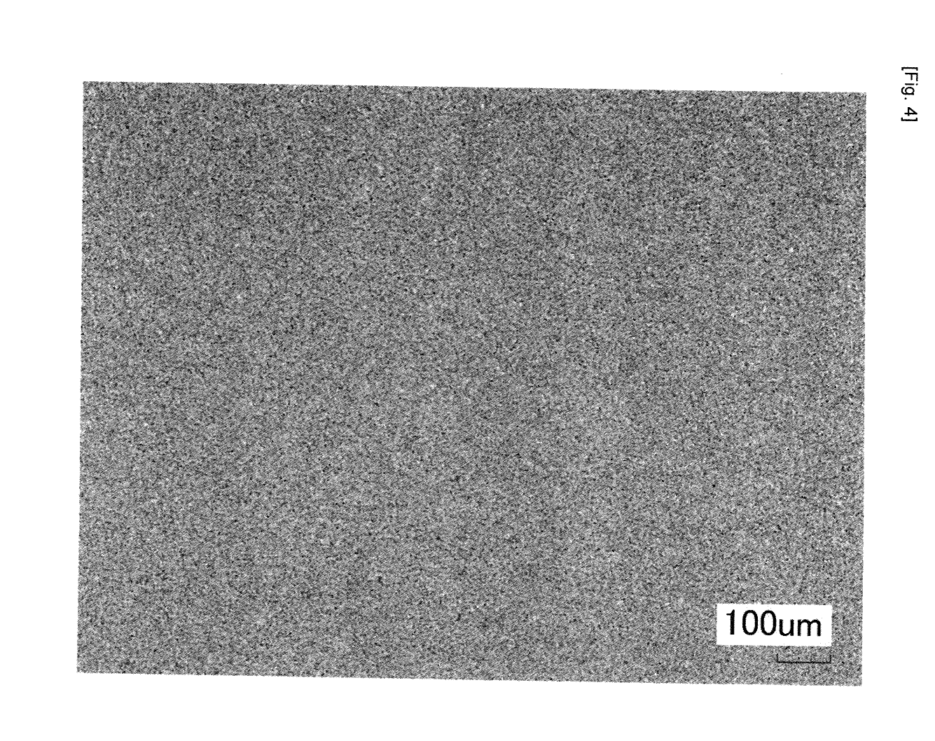

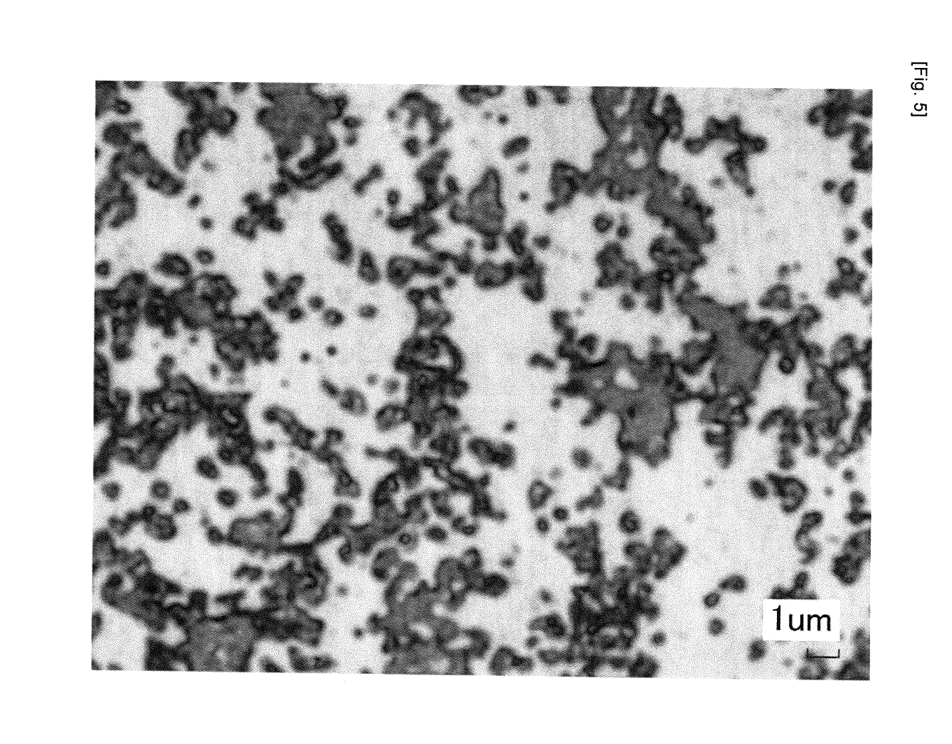

FIG. 3 shows a structural image of the polished surface of the target in Example 2 observed with an optical microscope, and FIG. 4 shows the image in Comparative Example 2-1. In FIG. 3, the blackish portion is the phase (A) in which the oxide is uniformly dispersed in a basis metal, and the white portion is the metal phase (B). FIG. 5 shows the structural image of a viewing field in which only the phase (A) of the target in Example 2 can be observed with an optical microscope.

In FIG. 5, the blackish portion corresponds to nonmagnetic oxide grains. The white portion corresponds to the basis metal. As shown in the structural image of FIG. 5, the distinctive feature in Example 2 is that no strong agglomeration of the oxide was observed.

### Comparative Example 2-2

In Comparative Example 2-2, a Co powder having an average grain diameter of 3 μm, a Cr powder having an average grain diameter of 5 μm, a Pt powder having an average grain diameter of 1 μm, a Ru powder having an average diameter of 8 μm, a SiO₂ powder having an average grain diameter of 1 μm, a Cr₂O₃ powder having an average grain diameter of 3 μm, and a Co atomized powder were prepared as raw material powders. These powders, the Co powder, the Cr powder, the Pt powder, the Ru powder, the SiO₂ powder, the Cr₂O₃ powder, and the Co atomized powder, were weighed to give a target composition of Co-9Cr-13Pt-4Ru-7SiO₂-3Cr₂O₃ (mol %). On this occasion, the amount of the Co powder was relatively decreased, and the amount of the Co atomized powder was increased.

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1100° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the area proportion of the oxide in the phase (A) of Comparative Example 2-2 was 58.00% and was higher than 50%. The average leakage magnetic flux density was 70.8% to give a target having a large leakage magnetic flux density, but the number of particles in the steady state was 48.1, which was significantly increased compared to that in Example 2.

### Example 3 and Comparative Example 3

In Example 3, a Co powder having an average grain diameter of 3 μm, a Cr powder having an average grain diameter of 5 μm, a Pt powder having an average grain diameter of 1 μm, a Co—B powder having an average grain diameter of 6 μm, a SiO₂ powder having an average grain diameter of 1 μm, and a Co atomized powder having a diameter in a range of 50 to 150 μm were prepared as raw material powders. These powders, the Co powder, the Cr powder, the Pt powder, the Co—B powder, the SiO₂ powder, and the Co atomized powder, were weighed to give a target composition of Co-13Cr-13Pt-3B-7SiO₂ (mol %).

Subsequently, the Co powder, the Cr powder, the Pt powder, the Co—B powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 900° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 3, a Co powder having an average grain diameter of 3 μm, a Cr powder having an average grain diameter of 5 μm, a Pt powder having an average grain diameter of 3 μm, a Co—B powder having an average diameter of 6 μm, and a SiO₂ powder having an average grain diameter of 1 μm were prepared as raw material powders. Neither Co coarse powder nor Co atomized powder was used. The powders, the Co powder, the Cr powder, the Pt powder, the Co—Bu powder, and the SiO₂ powder, were weighed to give a target composition of Co-13Cr-13Pt-3B-7SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 900° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 3 was 9.1 and was slightly higher than 8.8 in Comparative Example 3, but a target still with less particles compared to those in conventional targets was obtained. The average leakage magnetic flux density in Example 3 was 64.0% to give a target having a higher leakage magnetic flux density than 45.0% in Comparative Example 3.

The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 28.00% and was confirmed to be 50% or less.

### Example 4 and Comparative Example 4

In Example 4, a Co powder having an average grain diameter of 3 μm, a Cr powder having an average grain diameter of 5 μm, a Pt powder having an average grain diameter of 1 μm, a TiO₂ powder having an average grain diameter of 1 μm, a SiO₂ powder having an average grain diameter of 1 μm, a Cr₂O₃ powder having an average grain diameter of 3 μm, and a Co atomized powder having a diameter in a range of 50 to 150 μm were prepared as raw material powders. These powders, the Co powder, the Cr powder, the Pt powder, the TiO₂ powder, the SiO₂ powder, the Cr₂O₃ powder, and the Co atomized powder, were weighed to give a target composition of Co-8Cr-10Pt-3TiO₂-2SiO₂-4Cr₂O₃ (mol %).

Subsequently, the Co powder, the Cr powder, the Pt powder, the TiO₂ powder, the SiO₂ powder, and the Cr₂O₃ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 4, a Co powder having an average grain diameter of 3 μm, a Cr powder having an average grain diameter of 5 μm, a Pt powder having an average grain diameter of 1 μm, a TiO₂ powder having an average grain diameter of 1 μm, a SiO₂ powder having an average grain diameter of 1 μm, and a Cr₂O₃ powder having an average grain diameter of 3 μm were prepared as raw material powders. Neither Co coarse powder nor Co atomized powder was used. The powders, the Co powder, the Cr powder, the Pt powder, the TiO₂ powder, the SiO₂ powder, and the Cr₂O₃ powder, were weighed to give a target composition of Co-8Cr-10Pt-3TiO₂-7SiO₂-4Cr₂O₃ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 4 was 11.3 and was smaller than 12.2 in Comparative Example 4. The average leakage magnetic flux density in Example 4 was 38.4% to give a target having a higher leakage magnetic flux density than 33.5% in Comparative Example 4. The results of observation with an optical microscope demonstrate that the length of the short side of each rectangle circumscribed to the metal phase (B) was 2 to 200 μm, that the proportion of rectangles having a short side shorter than 2 μm was less than 5% and that no rectangles had a short side longer than 300 μm. It was confirmed that the aspect ratio ranged from 1:1 to 1:10 and that spherical and flat phases existed in a mixed state. The area proportion of the oxide in the phase (A) was 38.00% and was confirmed to be 50% or less.

### Example 5 and Comparative Example 5

In Example 5, a Co powder having an average grain diameter of 3 μm, a Cr powder having an average grain diameter of 5 μm, a Pt powder having an average grain diameter of 1 μm, a Ru powder having an average grain diameter of 8 μm, a SiO₂ powder having an average grain diameter of 1 μm, and a Co atomized powder having a diameter in a range of 50 to 150 μm were prepared as raw material powders. These powders, the Co powder, the Cr powder, the Pt powder, the Ru powder, the SiO₂ powder, and the Co atomized powder, were weighed to give a target composition of Co-10Cr-12Pt-2Ru-5SiO₂ (mol %).

Subsequently, the Co powder, the Cr powder, the Pt powder, the Ru powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 5, a Co powder having an average grain diameter of 3 μm, a Cr powder having an average grain diameter of 5 μm, a Pt powder having an average grain diameter of 1 μm, a Ru powder having an average grain diameter of 8 μm, and a SiO₂ powder having an average grain diameter of 1 μm were prepared as raw material powders. Neither Co coarse powder nor Co atomized powder was used. The powders, the Co powder, the Cr powder, the Pt powder, the Ru powder, and the SiO₂ powder, were weighed to give a target composition of Co-10Cr-12Pt-2Ru-5SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 5 was 6.1 and was slightly higher than 5.8 in Comparative Example 5, but a target still with less particles compared to those in conventional targets was obtained. The average leakage magnetic flux density in Example 5 was 40.8% to give a target having a higher leakage magnetic flux density than 34.6% in Comparative Example 5. The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 20.50% and was confirmed to be 50% or less.

### Example 6 and Comparative Example 6

In Example 6, a Co powder having an average grain diameter of 3 μm, a Cr powder having an average grain diameter of 5 μm, a Pt powder having an average grain diameter of 1 μm, a Co—B powder having an average grain diameter of 6 μm, a TiO₂ powder having an average grain diameter of 1 μm, a CoO powder having an average grain diameter of 1 μm, and a Co atomized powder having a diameter in a range of 50 to 150 μm were prepared as raw material powders. These powders, the Co powder, the Cr powder, the Pt powder, the Co—B powder, the TiO₂ powder, the CoO powder, and the Co atomized powder, were weighed to give a target composition of Co-18Cr-12Pt-3B-5TiO₂-8CoO (mol %).

Subsequently, the Co powder, the Cr powder, the Pt powder, the Co—B powder, the TiO₂ powder, and the CoO powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 6, a Co powder having an average grain diameter of 3 μm, a Cr powder having an average grain diameter of 5 μm, a Pt powder having an average grain diameter of 1 μm, a Co—B powder having an average grain diameter of 6 μm, a TiO₂ powder having an average grain diameter of 1 μm, and a CoO powder having an average grain diameter of 1 μm were prepared as raw material powders. Neither Co coarse powder nor Co atomized powder was used. The powders, the Co powder, the Cr powder, the Pt powder, the Co—B powder, the TiO₂ powder, and the CoO powder, were weighed to give a target composition of Co-18Cr-12Pt-3B-5TiO₂-8CoO (mol %).

These powders were charged into a 10-liter ball mill pot together with zirconia balls as the pulverizing medium, and the ball mill pot was sealed and rotated for 20 hours for mixing.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 6 was 17.5 and was slightly higher than 16.1 in Comparative Example 6, but a target still with less particles compared to those in conventional targets was obtained. The average leakage magnetic flux density in Example 6 was 73.2% to give a target having a higher leakage magnetic flux density than 61.6% in Comparative Example 6. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 42.80% and was confirmed to be 50% or less.

### Example 7 and Comparative Example 7

In Example 7, a Co powder having an average grain diameter of 3 μm, a Cr powder having an average grain diameter of 5 μm, a Pt powder having an average grain diameter of 1 μm, a Ta₂O₅ powder having an average grain diameter of 1 μm, a SiO₂ powder having an average grain diameter of 1 μm, and a Co atomized powder having a diameter in a range of 50 to 150 μm were prepared as raw material powders. These powders, the Co powder, the Cr powder, the Pt powder, the Ta₂O₅ powder, the SiO₂ powder, and the Co atomized powder, were weighed to give a target composition of Co-5Cr-15Pt-2Ta₂O₅-5SiO₂ (mol %).

Subsequently, the Co powder, the Cr powder, the Pt powder, the Ta₂O₅ powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 7, a Co powder having an average grain diameter of 3 μm, a Cr powder having an average grain diameter of 5 μm, a Pt powder having an average grain diameter of 1 μm, a Ta₂O₅ powder having an average grain diameter of 1 μm, and a SiO₂ powder having an average grain diameter of 1 μm were prepared as raw material powders. Neither Co coarse powder nor Co atomized powder was used. The powders, the Co powder, the Cr powder, the Pt powder, the Ta₂O₅ powder, and the SiO₂ powder, were weighed to give a target composition of Co-5Cr-15Pt-2Ta₂O₅-5SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 7 was 13.2 and was slightly higher than 12.2 in Comparative Example 7, but a target still with less particles compared to those in conventional targets was obtained. The average leakage magnetic flux density in Example 7 was 35.1% to give a target having a higher leakage magnetic flux density than 30.3% in Comparative Example 7.

The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 27.40% and was confirmed to be 50% or less.

### Example 8 and Comparative Example 8

In Example 8, a Co powder having an average grain diameter of 3 μm, a Cr powder having an average grain diameter of 5 μm, a Pt powder having an average grain diameter of 1 μm, a SiO₂ powder having an average grain diameter of 1 μm, a B₂O₃ powder having an average grain diameter of 10 μm, and a Co atomized powder having a diameter in a range of 50 to 150 μm were prepared as raw material powders. These powders, the Co powder, the Cr powder, the Pt powder, the SiO₂ powder, the 2B₂O₃ powder, and the Co atomized powder, were weighed to give a target composition of Co-14Cr-14Pt-3SiO₂-2B₂O₃ (mol %).

Subsequently, the Co powder, the Cr powder, the Pt powder, the SiO₂ powder, and the 2B₂O₃ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 900° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 8, a Co powder having an average grain diameter of 3 μm, a Cr powder having an average grain diameter of 5 μm, a Pt powder having an average grain diameter of 1 μm, a SiO₂ powder having an average grain diameter of 1 μm, and a B₂O₃ powder having an average grain diameter of 10 μm were prepared as raw material powders. Neither Co coarse powder nor Co atomized powder was used. The powders, the Co powder, the Cr powder, the Pt powder, the SiO₂ powder, and the 2B₂O₃ powder, were weighed to give a target composition of Co-14Cr-14Pt-3SiO₂-2B₂O₃ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 900° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 8 was 11.5 and was smaller than 12.2 in Comparative Example 8. The average leakage magnetic flux density in Example 8 was 65.3% to give a target having a higher leakage magnetic flux density than 56.6% in Comparative Example 8. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:9 and that spherical and flat phases existed in a mixed state. The area proportion of the oxide in the phase (A) was 39.00% and was confirmed to be 50% or less.

### Example 9 and Comparative Example 9

In Example 9, a Co powder having an average grain diameter of 3 μm, a Cr powder having an average grain diameter of 5 μm, a Pt powder having an average grain diameter of 1 μm, a TiO₂ powder having an average grain diameter of 1 μm, a SiO₂ powder having an average grain diameter of 1 μm, a Co₃O₄ powder having an average grain diameter of 1 μm, and a Co atomized powder having a diameter in a range of 50 to 150 μm were prepared as raw material powders. These powders, the Co powder, the Cr powder, the Pt powder, the TiO₂ powder, the SiO₂ powder, the Co₃O₄ powder, and the Co atomized powder, were weighed to give a target composition of Co-12Cr-16Pt-3TiO₂-3SiO₂-3Co₃O₄ (mol %).

Subsequently, the Co powder, the Cr powder, the Pt powder, the TiO₂ powder, the SiO₂ powder, and the Co₃O₄ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 9, a Co powder having an average grain diameter of 3 μm, a Cr powder having an average grain diameter of 5 μm, a Pt powder having an average grain diameter of 1 μm, a TiO₂ powder having an average grain diameter of 1 μm, a SiO₂ powder having an average grain diameter of 1 μm, and a Co₃O₄ powder having an average grain diameter of 1 μm were prepared as raw material powders. Neither Co coarse powder nor Co atomized powder was used. The powders, the Co powder, the Cr powder, the Pt powder, the TiO₂ powder, the SiO₂ powder, and the Co₃O₄ powder, were weighed to give a target composition of Co-12Cr-16Pt-3TiO₂-3SiO₂-3Co₃O₄ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 9 was 16.2 and was slightly higher than 14.3 in Comparative Example 9, but a target still with less particles compared to those in conventional targets was obtained. The average leakage magnetic flux density in Example 9 was 57.8% to give a target having a higher leakage magnetic flux density than 45.1% in Comparative Example 9. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 41.40% and was confirmed to be 50% or less.

### Example 10 and Comparative Example 10

In Example 10, a Co powder having an average grain diameter of 3 μm, a Cr powder having an average grain diameter of 5 μm, a Pt powder having an average grain diameter of 1 μm, a Mo powder having an average grain diameter of 3 μm, a TiO₂ powder having an average grain diameter of 1 μm, and a Co atomized powder having a diameter in a range of 50 to 150 μm were prepared as raw material powders. These powders, the Co powder, the Cr powder, the Pt powder, the Mo powder, the TiO₂ powder, and the Co atomized powder, were weighed to give a target composition of Co-6Cr-17Pt-2Mo-6TiO₂ (mol %).

Subsequently, the Co powder, the Cr powder, the Pt powder, the Mo powder, and the TiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 10, a Co powder having an average grain diameter of 3 μm, a Cr powder having an average grain diameter of 5 μm, a Pt powder having an average grain diameter of 1 μm, a Mo powder having an average grain diameter of 3 μm, and a TiO₂ powder having an average grain diameter of 1 μm were prepared as raw material powders. Neither Co coarse powder nor Co atomized powder was used. The powders, the Co powder, the Cr powder, the Pt powder, the Mo powder, and the TiO₂ powder, were weighed to give a target composition of Co-6Cr-17Pt-2Mo-6TiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 10 was 9.5 and was slightly higher than 8.7 in Comparative Example 10, but a target still with less particles compared to those in conventional targets was obtained. The average leakage magnetic flux density in Example 10 was 39.7% to give a target having a average leakage magnetic flux density than 31.2% in Comparative Example 10.

The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:9 and that spherical and flat phases existed in a mixed state. The area proportion of the oxide in the phase (A) was 34.50% and was confirmed to be 50% or less.

### Example 11 and Comparative Example 11

In Example 11, a Co powder having an average grain diameter of 3 μm, a Cr powder having an average grain diameter of 5 μm, a Pt powder having an average grain diameter of 1 μm, a Mn powder having an average grain diameter of 3 μm, a TiO₂ powder having an average grain diameter of 1 μm, a CoO powder having an average grain diameter of 1 μm, and a Co atomized powder having a diameter in a range of 50 to 150 μm were prepared as raw material powders. These powders, the Co powder, the Cr powder, the Pt powder, the Mn powder, the TiO₂ powder, the CoO powder, and the Co atomized powder, were weighed to give a target composition of Co-5Cr-20Pt-1Mn-8TiO₂-3CoO (mol %).

Subsequently, the Co powder, the Cr powder, the Pt powder, the Mn powder, the TiO₂ powder, and the CoO powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 11, a Co powder having an average grain diameter of 3 μm, a Cr powder having an average grain diameter of 5 μm, a Pt powder having an average grain diameter of 1 μm, a Mn powder having an average grain diameter of 3 μm, a TiO₂ powder having an average grain diameter of 1 μm, and a CoO powder having an average grain diameter of 1 μm were prepared as raw material powders. Neither Co coarse powder nor Co atomized powder was used. The powders, the Co powder, the Cr powder, the Pt powder, the Mn powder, the TiO₂ powder, and the CoO powder, were weighed to give a target composition of Co-5Cr-20Pt-1Mn-8TiO₂-3CoO (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 11 was 11.0 and was slightly higher than 10.5 in Comparative Example 10, but a target still with less particles compared to those in conventional targets was obtained. The average leakage magnetic flux density in Example 11 was 37.8% to give a target having a higher leakage magnetic flux density than 30.6% in Comparative Example 11.

The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 37.30% and was confirmed to be 50% or less.

### Example 12 and Comparative Example 12

In Example 12, a Co powder having an average grain diameter of 3 μm, a Cr powder having an average grain diameter of 5 μm, a Pt powder having an average grain diameter of 1 μm, a Ti powder having an average grain diameter of 1 μm, a SiO₂ powder having an average grain diameter of 1 μm, a CoO powder having an average grain diameter of 1 μm, and a Co atomized powder having a diameter in a range of 50 to 150 μm were prepared as raw material powders. These powders, the Co powder, the Cr powder, the Pt powder, the Ti powder, the SiO₂ powder, the CoO powder, and the Co atomized powder, were weighed to give a target composition of Co-6Cr-18Pt-2Ti-4SiO₂-2CoO (mol %).

Subsequently, the Co powder, the Cr powder, the Pt powder, the Ti powder, the SiO₂ powder, and the CoO powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 12, a Co powder having an average grain diameter of 3 μm, a Cr powder having an average grain diameter of 5 μm, a Pt powder having an average grain diameter of 1 μm, a Ti powder having an average grain diameter of 1 μm, a SiO₂ powder having an average grain diameter of 1 μm, and a CoO powder having an average grain diameter of 1 μm were prepared as raw material powders. Neither Co coarse powder nor Co atomized powder was used. The powders, the Co powder, the Cr powder, the Pt powder, the Ti powder, the SiO₂ powder, and the CoO powder, were weighed to give a target composition of Co-6Cr-18Pt-2Ti-4SiO₂-2CoO (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 12 was 9.8 and was smaller than 10.0 in Comparative Example 12. The average leakage magnetic flux density in Example 12 was 36.2% to give a target having a higher leakage magnetic flux density than 31.0% in Comparative Example 12. The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 36.80% and was confirmed to be 50% or less.

### Example 13 and Comparative Example 13

In Example 13, a Co powder having an average grain diameter of 3 μm, a Cr powder having an average grain diameter of 5 μm, a Ru powder having an average grain diameter of 8 μm, a SiO₂ powder having an average grain diameter of 1 μm, and a Co atomized powder having a diameter in a range of 50 to 150 μm were prepared as raw material powders. These powders, the Co powder, the Cr powder, the Ru powder, the SiO₂ powder, and the Co atomized powder, were weighed to give a target composition of Co-8Cr-6Ru-8SiO₂ (mol %).

Subsequently, the Co powder, the Cr powder, the Ru powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 13, a Co powder having an average grain diameter of 3 μm, a Cr powder having an average grain diameter of 5 μm, a Ru powder having an average grain diameter of 8 μm, and a SiO₂ powder having an average grain diameter of 1 μm were prepared as raw material powders. Neither Co coarse powder nor Co atomized powder was used. The powders, the Co powder, the Cr powder, the Ru powder, and the SiO₂ powder, were weighed to give a target composition of Co-8Cr-6Ru-8SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 13 was 10.6 and was smaller than 11.3 in Comparative Example 13. The average leakage magnetic flux density in Example 13 was 45.4% to give a target having a higher leakage magnetic flux density than 32.4% in Comparative Example 13. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 41.50% and was confirmed to be 50% or less.

### Example 14 and Comparative Example 14

In Example 14, a Co powder having an average grain diameter of 3 μm, a Cr powder having an average grain diameter of 5 μm, a TiO₂ powder having an average grain diameter of 1 μm, and a Co atomized powder having a diameter in a range of 50 to 150 μm were prepared as raw material powders. These powders, the Co powder, the Cr powder, the TiO₂ powder, and the Co atomized powder, were weighed to give a target composition of Co-20Cr-10TiO₂ (mol %).

Subsequently, the Co powder, the Cr powder, and the 110₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 14, a Co powder having an average grain diameter of 3 μm, a Cr powder having an average grain diameter of 5 μm, and a TiO₂ powder having an average grain diameter of 1 μm were prepared as raw material powders. Neither Co coarse powder nor Co atomized powder was used. The powders, the Co powder, the Cr powder, and the TiO₂ powder, were weighed to give a target composition of Co-20Cr-10TiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 14 was 7.8 and was slightly higher than 7.6 in Comparative Example 14, but a target still with less particles compared to those in conventional targets was obtained. The average leakage magnetic flux density in Example 14 was 95.4% to give a target having a higher leakage magnetic flux density than 80.2% in Comparative Example 14. The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 40.00% and was confirmed to be 50% or less.

### Example 15 and Comparative Example 15

In Example 15, a Co powder having an average grain diameter of 3 μm, a Cr powder having an average grain diameter of 5 μm, a SiO₂ powder having an average grain diameter of 1 μm, and a Co atomized powder having a diameter in a range of 50 to 150 μm were prepared as raw material powders. These powders, the Co powder, the Cr powder, the SiO₂ powder, and the Co atomized powder, were weighed to give a target composition of Co-15Cr-12SiO₂ (mol %).

Subsequently, the Co powder, the Cr powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 15, a Co powder having an average grain diameter of 3 μm, a Cr powder having an average grain diameter of 5 μm, and a SiO₂ powder having an average grain diameter of 1 μm were prepared as raw material powders. Neither Co coarse powder nor Co atomized powder was used. The powders, the Co powder, the Cr powder, and the SiO₂ powder, were weighed to give a target composition of Co-15Cr-12SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 15 was 11.1 and was slightly higher than 10.6 in Comparative Example 15, but a target still with less particles compared to those in conventional targets was obtained. The average leakage magnetic flux density in Example 15 was 64.5% to give a target having a higher leakage magnetic flux density than 51.1% in Comparative Example 15. The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 39.60% and was confirmed to be 50% or less.

### Example 16 and Comparative Example 16

In Example 16, a Co powder having an average grain diameter of 3 μm, a Cr powder having an average grain diameter of 5 μm, a Ru powder having an average grain diameter of 8 μm, a TiO₂ powder having an average grain diameter of 1 μm, a CoO powder having an average grain diameter of 1 μm, and a Co atomized powder having a diameter in a range of 50 to 150 μm were prepared as raw material powders. These powders, the Co powder, the Cr powder, the Ru powder, the TiO₂ powder, the CoO powder, and the Co atomized powder, were weighed to give a target composition of Co-16Cr-3Ru-5TiO₂-3CoO (mol %).

Subsequently, the Co powder, the Cr powder, the Ru powder, the TiO₂ powder, and the CoO powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 16, a Co powder having an average grain diameter of 3 μm, a Cr powder having an average grain diameter of 5 μm, a Ru powder having an average grain diameter of 8 μm, a TiO₂ powder having an average grain diameter of 1 μm, and a CoO powder having an average grain diameter of 1 μm were prepared as raw material powders. Neither Co coarse powder nor Co atomized powder was used. The powders, the Co powder, the Cr powder, the Ru powder, the TiO₂ powder, the CoO powder, and the Co atomized powder, were weighed to give a target composition of Co-16Cr-3Ru-5TiO₂-3CoO (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 16 was 12.4 and was slightly higher than 11.7 in Comparative Example 16, but a target still with less particles compared to those in conventional targets was obtained. The average leakage magnetic flux density in Example 16 was 70.1% to give a target having a higher leakage magnetic flux density than 58.0% in Comparative Example 16. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 42.10% and was confirmed to be 50% or less.

### Example 17 and Comparative Example 17

In Example 17, a Co powder having an average grain diameter of 3 μm, a Cr powder having an average grain diameter of 5 μm, a Pt powder having an average grain diameter of 1 μm, a Ta powder having an average grain diameter of 30 μm, a SiO₂ powder having an average grain diameter of 1 μm, and Co atomized powder having a diameter in a range of 50 to 150 μm were prepared as raw material powders. These powders, the Co powder, the Cr powder, the Pt powder, the Ta powder, the SiO₂ powder, and the Co atomized powder, were weighed to give a target composition of Co-8Cr-20Pt-3Ta-3SiO₂ (mol %).

Subsequently, the Co powder, the Cr powder, the Pt powder, the Ta powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 17, a Co powder having an average grain diameter of 3 μm, a Cr powder having an average grain diameter of 5 μm, a Pt powder having an average grain diameter of 1 μm, a Ta powder having an average grain diameter of 30 μm, and a SiO₂ powder having an average grain diameter of 1 μm were prepared. Neither Co coarse powder nor Co atomized powder was used. The powders, the Co powder, the Cr powder, the Pt powder, the Ta powder, and the SiO₂ powder, were weighed to give a target composition of Co-8Cr-20Pt-3Ta-3SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 17 was 6.8 and was smaller than 7.2 in Comparative Example 17. The average leakage magnetic flux density in Example 16 was 56.1% to give a target having a higher leakage magnetic flux density than 58.0% in Comparative Example 17. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 17.00% and was confirmed to be 50% or less.

### Example 18 and Comparative Example 18

In Example 18, a Co powder having an average grain diameter of 3 μm, a Cr powder having an average grain diameter of 5 μm, a Pt powder having an average grain diameter of 1 μm, a W powder having an average grain diameter of 5 μm, a B₂O₃ powder having an average grain diameter of 10 μm, a Ta₂O₅ powder having an average grain diameter of 1 μm, a Cr₂O₃ powder having an average grain diameter of 3 μm, and a Co atomized powder having a diameter in a range of 50 to 150 μm were prepared as raw material powders. These powders, the Co powder, the Cr powder, the Pt powder, the W powder, the B₂O₃ powder, the Ta₂O₃ powder, the Cr₂O₃ powder, and the Co atomized powder, were weighed to give a target composition of Co-8Cr-21Pt-0.7W-3B₂O₃-1Ta₂O₅-1Cr₂O₃ (mol %).

Subsequently, the Co powder, the Cr powder, the Pt powder, the W powder, the B₂O₃ powder, the Ta₂O₃ powder, and the Cr₂O₃ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1000° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 18, a Co powder having an average grain diameter of 3 μm, Cr powder having an average grain diameter of 5 μm, a Pt powder having an average grain diameter of 1 μm, a W powder having an average grain diameter of 5 μm, a B₂O₃ powder having an average grain diameter of 10 μm, a Ta₂O₅ powder having an average grain diameter of 1 μm, and a Cr₂O₃ powder having an average grain diameter of 3 μm were prepared as raw material powders. Neither Co coarse powder nor Co atomized powder was used. The powders, the Co powder, the Cr powder, the Pt powder, the W powder, the B₂O₃ powder, the Ta₂O₃ powder, and the Cr₂O₃ powder, weighed to give a target composition of Co-8Cr-21Pt-0.7W-3B₂O₃-1Ta₂O₅-1Cr₂O₃ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1000° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, the number of particles in the steady state in Example 18 was 11.8 and was slightly higher than 11.6 in Comparative Example 18, but a target still with less particles compared to those in conventional targets was obtained. The average leakage magnetic flux density in Example 18 was 47.5% to give a target having a higher leakage magnetic flux density than 38.3% in Comparative Example 18. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:8 and that spherical and flat phases existed in a mixed state. The area proportion of the oxide in the phase (A) was 34.00% and was confirmed to be 50% or less.

### Example 19 and Comparative Example 19

In Example 19, a Co powder having an average grain diameter of 3 μm, a Pt powder having an average grain diameter of 1 μm, a TiO₂ powder having an average grain diameter of 1 μm, a SiO₂ powder having an average grain diameter of 1 μm, and a Co atomized powder having a diameter in a range of 50 to 150 μm were prepared as raw material powders. These powders, the Co powder, the Pt powder, the TiO₂ powder, the SiO₂ powder, and the Co atomized powder, were weighed to give a target composition of Co-18Pt-8TiO₂-2SiO₂ (mol %).

Subsequently, the Co powder, the Pt powder, the TiO₂ powder, and the SiO₂ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

Subsequently, the resulting powder mixture was loaded in a carbon mold and was hot-pressed in a vacuum atmosphere under conditions of a temperature of 1000° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 19, a Co powder having an average grain diameter of 3 μm, a Pt powder having an average grain diameter of 1 μm, a TiO₂ powder having an average grain diameter of 1 μm, and a SiO₂ powder having an average grain diameter of 1 μm were prepared as raw material powders. Neither Co coarse powder nor Co atomized powder was used. The powders, the Co powder, the Pt powder, the TiO₂ powder, and the SiO₂ powder, were weighed to give a target composition of Co-18Pt-8TiO₂-2SiO₂ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1000° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 19 was 13.4 and was smaller than 13.7 in Comparative Example 19. The average leakage magnetic flux density in Example 19 was 40.5% to give a target having a higher leakage magnetic flux density than 33.2% in Comparative Example 19. The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 29.00% and was confirmed to be 50% or less.

### Example 20 and Comparative Example 20

In Example 20, a Co powder having an average grain diameter of 3 μm, a Pt powder having an average grain diameter of 1 μm, a SiO₂ powder having an average grain diameter of 1 μm, a Cr₂O₃ powder having an average grain diameter of 3 μm, and a Co atomized powder having a diameter in a range of 50 to 150 μm were prepared as raw material powders. These powders, the Co powder, the Pt powder, the SiO₂ powder, the Cr₂O₃ powder, and the Co atomized powder, were weighed to give a target composition of Co-22Pt-6SiO₂-3Cr₂O₃ (mol %).

Subsequently, the Co powder, the Pt powder, the SiO₂ powder, and the Cr₂O₃ powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 20, a Co powder having an average grain diameter of 3 μm, a Pt powder having an average grain diameter of 1 μm, a SiO₂ powder having an average grain diameter of 1 μm, and a Cr₂O₃ powder having an average grain diameter of 3 μm were prepared as raw material powders. Neither Co coarse powder nor Co atomized powder was used. The powders, the Co powder, the Pt powder, the SiO₂ powder, and the Cr₂O₃ powder, were weighed to give a target composition of Co-22Pt-6SiO₂-3Cr₂O₃ (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 20 was 11.8 and was smaller than 11.0 in Comparative Example 20. The average leakage magnetic flux density in Example 20 was 41.1% to give a target having a higher leakage magnetic flux density than 33.6% in Comparative Example 20. The results of observation with an optical microscope demonstrate that the length of the short side of each rectangle circumscribed to the metal phase (B) was 2 to 200 μm, that the proportion of rectangles having a short side shorter than 2 μm was less than 5%, and that no rectangles had a short side longer than 300 μm. It was confirmed that the aspect ratio ranged from 1:1 to 1:10 and that spherical and flat phases existed in a mixed state. The area proportion of the oxide in the phase (A) was 37.00% and was confirmed to be 50% or less.

### Example 21 and Comparative Example 21

In Example 21, a Co powder having an average grain diameter of 3 μm, a Pt powder having an average grain diameter of 1 μm, a Ru powder having an average grain diameter of 8 μm, a TiO₂ powder having an average grain diameter of 1 μm, a CoO powder having an average grain diameter of 1 μm, and a Co atomized powder having a diameter in a range of 50 to 150 μm were prepared as raw material powders. These powders, the Co powder, the Pt powder, the Ru powder, the TiO₂ powder, the CoO powder, and the Co atomized powder, were weighed to give a target composition of Co-16Pt-4Ru-7TiO₂-6CoO (mol %).

Subsequently, the Co powder, the Pt powder, the Ru powder, the TiO₂ powder, and the CoO powder were charged into a 10-liter ball mill pot together with zirconia balls as the pulverizing medium, and the ball mill pot was sealed and rotated for 20 hours for mixing. The resulting powder mixture was mixed with the Co atomized powder with a planetary-screw mixer having a ball capacity of about 7 liters for 10 minutes.

The resulting powder mixture was loaded in a carbon mold and was hot-pressed in a vacuum atmosphere under conditions of a temperature of 1000° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

In Comparative Example 21, a Co powder having an average grain diameter of 3 μm, a Pt powder having an average grain diameter of 1 μm, a Ru powder having an average grain diameter of 8 μm, a TiO₂ powder having an average grain diameter of 1 μm, and a CoO powder having an average grain diameter of 1 μm were prepared as raw material powders. Neither Co coarse powder nor Co atomized powder was used. The powders, the Co powder, the Pt powder, the Ru powder, the TiO₂ powder, and the CoO powder, were weighed to give a target composition of Co-16Pt-4Ru-7TiO₂-6CoO (mol %).

These powders were charged into a 10-liter ball mill pot together with zirconia balls as the pulverizing medium, and the ball mill pot was sealed and rotated for 20 hours for mixing.

Subsequently, the resulting powder mixture was loaded in a carbon mold and was hot-pressed in a vacuum atmosphere under conditions of a temperature of 1000° C., a retention time of 2 hours, and a pressure of 30 MPa to give a sintered compact. The sintered compact was cut with a lathe to give a disk-shaped target having a diameter of 180 mm and a thickness of 5 mm, followed by counting the number of particles and measuring the average leakage magnetic flux density. The results are shown in Table 1.

As shown in Table 1, it was confirmed that the number of particles in the steady state in Example 21 was 12.4 and was smaller than 12.9 in Comparative Example 21. The average leakage magnetic flux density in Example 21 was 43.8% to give a target having a higher leakage magnetic flux density than 32.8% in Comparative Example 21. The results of observation with an optical microscope demonstrate that the length of the short side of each rectangle circumscribed to the metal phase (B) was 5 to 200 μm, that the proportion of rectangles having a short side shorter than 2 μm was less than 5%, and that no rectangles had a short side longer than 300 μm. It was confirmed that the aspect ratio ranged from 1:1 to 1:9 and that spherical and flat phases existed in a mixed state. The area proportion of the oxide in the phase (A) was 36.90% and was confirmed to be 50% or less.

TABLE 1

| | Composition | | Molar ratio | | | |
|---|---|---|---|---|---|---|
| Example 1 | Co—Cr—Pt—SiO₂ | | Co—12Cr—14Pt—8SiO₂ (mol %) | | | |
| Comparative Example 1 | Co—Cr—Pt—SiO₂ | | Co—12Cr—14Pt—8SiO₂ (mol %) | | | |
| Example 2 | Co—Cr—Pt—Ru—SiO₂—Cr₂O₃ | | Co—9Cr—13Pt—4Ru—7SiO₂—3Cr₂O₃ (mol %) | | | |
| Comparative Example 2-1 | Co—Cr—Pt—Ru—SiO₂—Cr₂O₃ | | Co—9Cr—13Pt—4Ru—7SiO₂—3Cr₂O₃ (mol %) | | | |
| Comparative Example 2-2 | Co—Cr—Pt—Ru—SiO₂—Cr₂O₃ | | Co—9Cr—13Pt—4Ru—7SiO₂—3Cr₂O₃ (mol %) | | | |
| Example 3 | Co—Cr—Pt—B—SiO₂ | | Co—13Cr—13Pt—3B—7SiO₂ (mol %) | | | |
| Comparative Example 3 | Co—Cr—Pt—B—SiO₂ | | Co—13Cr—13Pt—3B—7SiO₂ (mol %) | | | |
| Example 4 | Co—Cr—Pt—TiO₂—SiO₂—Cr₂O₃ | | Co—8Cr—10Pt—3TiO₂—2SiO₂—4Cr₂O₃ (mol %) | | | |
| Comparative Example 4 | Co—Cr—Pt—TiO₂—SiO₂—Cr₂O₃ | | Co—8Cr—10Pt—3TiO₂—2SiO₂—4Cr₂O₃ (mol %) | | | |
| Example 5 | Co—Cr—Pt—Ru—SiO₂ | | Co—10Cr—12Pt—2Ru—5SiO₂ (mol %) | | | |
| Comparative Example 5 | Co—Cr—Pt—Ru—SiO₂ | | Co—10Cr—12Pt—2Ru—5SiO₂ (mol %) | | | |
| Example 6 | Co—Cr—Pt—B—TiO₂—CoO | | Co—18Cr—12Pt—3B—5TiO₂—8CoO (mol %) | | | |
| Comparative Example 6 | Co—Cr—Pt—B—TiO₂—CoO | | Co—18Cr—12Pt—3B—5TiO₂—8CoO (mol %) | | | |
| Example 7 | Co—Cr—Pt—Ta₂O₅—SiO₂ | | Co—5Cr—15Pt—2Ta₂O₅—5SiO₂ (mol %) | | | |
| Comparative Example 7 | Co—Cr—Pt—Ta₂O₅—SiO₂ | | Co—5Cr—15Pt—2Ta₂O₅—5SiO₂ (mol %) | | | |
| Example 8 | Co—Cr—Pt—SiO₂—B₂O₃ | | Co—14Cr—14Pt—3SiO₂—2B₂O₃ (mol %) | | | |
| Comparative Example 8 | Co—Cr—Pt—SiO₂—B₂O₃ | | Co—14Cr—14Pt—3SiO₂—2B₂O₃ (mol %) | | | |
| Example 9 | Co—Cr—Pt—TiO₂—SiO₂—Co₃O₄ | | Co—12Cr—16Pt—3TiO₂—3SiO₂—3Co₃O₄ (mol %) | | | |
| Comparative Example 9 | Co—Cr—Pt—TiO₂—SiO₂—Co₃O₄ | | Co—12Cr—16Pt—3TiO₂—3SiO₂—3Co₃O₄ (mol %) | | | |
| Example 10 | Co—Cr—Pt—Mo—TiO₂ | | Co—6Cr—17Pt—2Mo—6TiO₂ (mol %) | | | |
| Comparative Example 10 | Co—Cr—Pt—Mo—TiO₂ | | Co—6Cr—17Pt—2Mo—6TiO₂ (mol %) | | | |
| Example 11 | Co—Cr—Pt—Mn—TiO₂—CoO | | Co—5Cr—20Pt—1Mn—8TiO₂—3CoO (mol %) | | | |
| Comparative Example 11 | Co—Cr—Pt—Mn—TiO₂—CoO | | Co—5Cr—20Pt—1Mn—8TiO₂—3CoO (mol %) | | | |
| Example 12 | Co—Cr—Pt—Ti—SiO₂—CoO | | Co—6Cr—18Pt—2Ti—4SiO₂—2CoO (mol %) | | | |
| Comparative Example 12 | Co—Cr—Pt—Ti—SiO₂—CoO | | Co—6Cr—18Pt—2Ti—4SiO₂—2CoO (mol %) | | | |
| Example 13 | Co—Cr—Ru—SiO₂ | | Co—8Cr—6Ru—8SiO₂ (mol %) | | | |
| Comparative Example 13 | Co—Cr—Ru—SiO₂ | | Co—8Cr—6Ru—8SiO₂ (mol %) | | | |
| Example 14 | Co—Cr—TiO₂ | | Co—20Cr—10TiO2 (mol %) | | | |
| Comparative Example 14 | Co—Cr—TiO₂ | | Co—20Cr—10TiO2 (mol %) | | | |
| Example 15 | Co—Cr—SiO₂ | | Co—15Cr—12SiO₂ (mol %) | | | |
| Comparative Example 15 | Co—Cr—SiO₂ | | Co—15Cr—12SiO₂ (mol %) | | | |
| Example 16 | Co—Cr—Ru—TiO₂—CoO | | Co—16Cr—3Ru—5TiO₂—3CoO (mol %) | | | |
| Comparative Example 16 | Co—Cr—Ru—TiO₂—CoO | | Co—16Cr—3Ru—5TiO₂—3CoO (mol %) | | | |
| Example 17 | Co—Cr—Pt—Ta—SiO₂ | | Co—8Cr—20Pt—3Ta—3SiO₂ (mol %) | | | |
| Comparative Example 17 | Co—Cr—Pt—Ta—SiO₂ | | Co—8Cr—20Pt—3Ta—3SiO₂ (mol %) | | | |
| Example 18 | Co—Cr—Pt—W—B₂O₃—Ta₂O₅—Cr₂O₃ | | Co—8Cr—21Pt—0.7W—3B₂O₃—1Ta₂O₅—1Cr₂O₃ (mol %) | | | |
| Comparative Example 18 | Co—Cr—Pt—W—B₂O₃—Ta₂O₅—Cr₂O₃ | | Co—8Cr—21Pt—0.7W—3B₂O₃—1Ta₂O₅—1Cr₂O₃ (mol %) | | | |
| Example 19 | Co—Pt—TiO₂—SiO₂ | | Co—18Pt—8TiO₂—2SiO₂ (mol %) | | | |
| Comparative Example 19 | Co—Pt—TiO₂—SiO₂ | | Co—18Pt—8TiO₂—2SiO₂ (mol %) | | | |
| Example 20 | Co—Pt—SiO₂—Cr₂O₃ | | Co—22Pt—6SiO₂—3Cr₂O₃ (mol %) | | | |
| Comparative Example 20 | Co—Pt—SiO₂—Cr₂O₃ | | Co—22Pt—6SiO₂—3Cr₂O₃ (mol %) | | | |
| Example 21 | Co—Pt—Ru—TiO₂—CoO | | Co—16Pt—4Ru—7TiO₂—6CoO (mol %) | | | |
| Comparative Example 21 | Co—Pt—Ru—TiO₂—CoO | | Co—16Pt—4Ru—7TiO₂—6CoO (mol %) | | | |
| | | Length of minor | Aspect-ratio | Area proportion | Number of | Average |
| | | axis of rectangle | distribution of | of | particles | leakage |
| | | circumscribed to | metal phase | oxide in | in a steady | magnetic |
| | Type of coarse particle | phase (B) (μm) | (B) | phase (A) | state | flux density |
| Example 1 | Co coarse powder | 2 to 300 | 1:1 to 1:15 | 38.00% | 10.2 | 61.3% |
| Comparative Example 1 | Not use coarse powder | — | — | — | 10.4 | 47.1% |
| Example 2 | Co atomized powder | 5 to 200 | 1:1 to 1:8 | 50.00% | 11.1 | 65.7% |
| Comparative Example 2-1 | Not use coarse powder | — | — | — | 10.5 | 40.1% |
| Comparative Example 2-2 | Co atomized powder | 5 to 200 | 1:1 to 1:8 | 58.00% | 48.1 | 70.8% |
| Example 3 | Co atomized powder | 5 to 200 | 1:1 to 1:8 | 28.00% | 9.1 | 64.0% |
| Comparative Example 3 | Not use coarse powder | — | — | — | 8.8 | 45.0% |
| Example 4 | Co atomized powder | 2 to 200 | 1:1 to 1:10 | 38.00% | 11.3 | 38.4% |
| Comparative Example 4 | Not use coarse powder | — | — | — | 12.2 | 33.5% |
| Example 5 | Co atomized powder | 2 to 200 | 1:1 to 1:10 | 20.50% | 6.1 | 40.8% |
| Comparative Example 5 | Not use coarse powder | — | — | — | 5.8 | 34.6% |
| Example 6 | Co atomized powder | 5 to 200 | 1:1 to 1:8 | 42.80% | 17.5 | 73.2% |
| Comparative Example 6 | Not use coarse powder | — | — | — | 16.1 | 61.6% |
| Example 7 | Co atomized powder | 2 to 200 | 1:1 to 1:10 | 27.40% | 13.2 | 35.1% |
| Comparative Example 7 | Not use coarse powder | — | — | — | 12.2 | 30.3% |
| Example 8 | Co atomized powder | 5 to 200 | 1:1 to 1:9 | 39.00% | 11.5 | 65.3% |
| Comparative Example 8 | Not use coarse powder | — | — | — | 12.4 | 56.6% |
| Example 9 | Co atomized powder | 5 to 200 | 1:1 to 1:8 | 41.40% | 16.2 | 57.8% |
| Comparative Example 9 | Not use coarse powder | — | — | — | 14.3 | 45.1% |
| Example 10 | Co atomized powder | 5 to 200 | 1:1 to 1:9 | 34.50% | 9.5 | 39.7% |
| Comparative Example 10 | Not use coarse powder | — | — | — | 8.7 | 31.2% |
| Example 11 | Co atomized powder | 5 to 200 | 1:1 to 1:8 | 37.30% | 11.0 | 37.8% |
| Comparative Example 11 | Not use coarse powder | — | — | — | 10.5 | 30.6% |
| Example 12 | Co atomized powder | 2 to 200 | 1:1 to 1:10 | 36.80% | 9.8 | 36.2% |
| Comparative Example 12 | Not use coarse powder | — | — | — | 10.0 | 31.0% |
| Example 13 | Co atomized powder | 5 to 200 | 1:1 to 1:8 | 41.50% | 10.6 | 45.4% |
| Comparative Example 13 | Not use coarse powder | — | — | — | 11.3 | 32.4% |
| Example 14 | Co atomized powder | 2 to 200 | 1:1 to 1:10 | 40.00% | 7.8 | 95.4% |
| Comparative Example 14 | Not use coarse powder | — | — | — | 7.6 | 80.2% |
| Example 15 | Co atomized powder | 2 to 200 | 1:1 to 1:10 | 39.60% | 11.1 | 64.5% |
| Comparative Example 15 | Not use coarse powder | — | — | — | 10.6 | 51.1% |
| Example 16 | Co atomized powder | 5 to 200 | 1:1 to 1:8 | 42.10% | 12.4 | 70.1% |
| Comparative Example 16 | Not use coarse powder | — | — | — | 11.7 | 58.0% |
| Example 17 | Co atomized powder | 5 to 200 | 1:1 to 1:8 | 17.00% | 6.8 | 56.1% |
| Comparative Example 17 | Not use coarse powder | — | — | — | 7.2 | 40.1% |
| Example 18 | Co atomized powder | 5 to 200 | 1:1 to 1:8 | 34.00% | 11.8 | 47.5% |
| Comparative Example 18 | Not use coarse powder | — | — | — | 11.6 | 38.3% |
| Example 19 | Co atomized powder | 2 to 200 | 1:1 to 1:10 | 29.00% | 13.4 | 40.5% |
| Comparative Example 19 | Not use coarse powder | — | — | — | 13.7 | 33.2% |
| Example 20 | Co atomized powder | 2 to 200 | 1:1 to 1:10 | 37.00% | 11.8 | 41.1% |
| Comparative Example 20 | Not use coarse powder | — | — | — | 11.0 | 33.6% |
| Example 21 | Co atomized powder | 5 to 200 | 1:1 to 1:9 | 36.90% | 12.4 | 43.8% |
| Comparative Example 21 | Not use coarse powder | — | — | — | 12.9 | 32.8% |

In all Examples 1 to 21, the length of the short side of each rectangle circumscribed to the metal phase (B) was 2 to 300 μm; the proportion of rectangles having a short side shorter than 2 μm was less than 5%; and no rectangles had a short side longer than 300 μm. It was confirmed that the aspect ratio ranged from 1:1 to 1:15 and that the area proportion of oxide in the phase (A) was 50% or less. It is shown that such a composition structure suppresses particle generation, achieves uniform erosion, and has a very important role in improvement of the leakage magnetic flux.

### INDUSTRIAL APPLICABILITY

The present invention can significantly suppress the particle generation and can improve the leakage magnetic flux by adjusting the composition structure of a ferromagnetic sputtering target. Accordingly, the use of the target of the present invention can provide stable discharge in sputtering with a magnetron sputtering apparatus. In addition, it is possible to increase the thickness of the target, which allows the target life to lengthen and allows to form a magnetic thin film at a low cost. Furthermore, it is possible to considerably improve the quality of a film formed by sputtering. The target is useful as the ferromagnetic sputtering target that is used for forming a magnetic thin film of a magnetic recording medium, in particular, for forming the recording layer of a hard disk drive.

1. A nonmagnetic-material-dispersed sputtering target having a metal composition comprising 20 mol % or less of Cr and the balance of Co, wherein:
the target structure includes a phase (A) in which a nonmagnetic oxide material is dispersed in a basis metal, and a metal phase (B) containing 40 mol % or more of Co;
the area proportion of grains of the nonmagnetic oxide material in the phase (A) is 50% or less; and
when a minimum-area rectangle circumscribed to the phase (B) is assumed, the aspect ratio of the circumscribed rectangle is in a range of 1:1 to 1:15 in all of the phases (B) and the proportion of the circumscribed rectangle having a short side of 2 to 300 μm is 90% or more of all of the phases (B).

2. A nonmagnetic-material-dispersed sputtering target having a metal composition comprising 20 mol % or less of Cr, 5 mol % or more and 30 mol % or less of Pt, and the balance of Co, wherein:
the target structure includes a phase (A) in which a nonmagnetic oxide material is dispersed in a basis metal, and a metal phase (B) containing 40 mol % or more of Co;
the area proportion of grains of the nonmagnetic oxide material in the phase (A) is 50% or less; and
when a minimum-area rectangle circumscribed to the metal phase (B) is assumed, the aspect ratio of the circumscribed rectangle is in a range of 1:1 to 1:15 in all of the phases (B) and the proportion of the circumscribed rectangle having a short side of 2 to 300 μm is 90% or more of all of the phases (B).

3. A nonmagnetic-material-dispersed sputtering target having a metal composition comprising 5 mol % or more and 30 mol % or less 30 of Pt and the balance of Co, wherein:
the target structure includes a phase (A) in which a nonmagnetic oxide material is dispersed in a basis metal, and a metal phase (B) containing 40 mol % or more of Co;
the area proportion of grains of the nonmagnetic oxide material in the phase (A) is 50% or less; and
when a minimum-area rectangle circumscribed to the phase (B) is assumed, the aspect ratio of the circumscribed rectangle is in a range of 1:1 to 1:15 in all of the phases (B) and the proportion of the circumscribed rectangle having a short side of 2 to 300 μm is 90% or more of all of the phases (B).

4. The nonmagnetic-material-dispersed ferromagnetic sputtering target according to claim 3, wherein the area proportion of grains of the nonmagnetic oxide material in the phase (A) is 17% or more and 50% or less.

5. The ferromagnetic sputtering target according to claim 4, wherein the basis metal further comprises at least one additional element selected from B, Ti, V, Mn, Zr, Nb, Ru, Mo, Ta and W in an amount of 0.5 mol % or more and 10 mol % or less, and the balance is Co.

6. The ferromagnetic sputtering target according to claim 3, wherein the basis metal further comprises at least one additional element selected from B, Ti, V, Mn, Zr, Nb, Ru, Mo, Ta and W in an amount of 0.5 mol % or more and 10 mol % or less, and the balance is Co.

7. The nonmagnetic-material-dispersed ferromagnetic sputtering target according to claim 2, wherein the area proportion of grains of the nonmagnetic oxide material in the phase (A) is 17% or more and 50% or less.

8. The ferromagnetic sputtering target according to claim 7, wherein the basis metal further comprises at least one additional element selected from B, Ti, V, Mn, Zr, Nb, Ru, Mo, Ta and W in an amount of 0.5 mol % or more and 10 mol % or less, and the balance is Co.

9. The ferromagnetic sputtering target according to claim 2, wherein the basis metal further comprises at least one additional element selected from B, Ti, V, Mn, Zr, Nb, Ru, Mo, Ta and W in an amount of 0.5 mol % or more and 10 mol % or less, and the balance is Co.

10. The nonmagnetic-material-dispersed ferromagnetic sputtering target according to claim 1, wherein the area proportion of grains of the nonmagnetic oxide material in the phase (A) is 17% or more and 50% or less.

11. The ferromagnetic sputtering target according to claim 10, wherein the basis metal further comprises at least one additional element selected from B, Ti, V, Mn, Zr, Nb, Ru, Mo, Ta and W in an amount of 0.5 mol % or more and 10 mol % or less, and the balance is Co.

12. The ferromagnetic sputtering target according to claim 1, wherein the basis metal further comprises at least one additional element selected from B, Ti, V, Mn, Zr, Nb, Ru, Mo, Ta and W in an amount of 0.5 mol % or more and 10 mol % or less, and the balance is Co.
